(19) United States
(12) Patent Application Publication
(10) Pub. No.: US 2025/0287681 A1
(43) Pub. Date: Sep. 11, 2025

(54) NITRIDE SEMICONDUCTOR DEVICE AND METHOD FOR MANUFACTURING THE NITRIDE SEMICONDUCTOR DEVICE

(71) Applicant: Panasonic Holdings Corporation, Osaka (JP)

(72) Inventors: Naoki TORII, Osaka (JP); Hiroyuki Handa, Osaka (JP); Daisuke Shibata, Kyoto (JP); Satoshi Tamura, Osaka (JP)

(21) Appl. No.: 19/215,730

(22) Filed: May 22, 2025

Related U.S. Application Data
(63) Continuation of application No. PCT/JP2023/039964, filed on Nov. 7, 2023.

(30) Foreign Application Priority Data
Dec. 1, 2022 (JP) 2022-192577

(51) Int. Cl. H10D 84/00; H10D 30/01; H10D 30/47; H10D 30/66; H10D 62/10; H10D 64/00; H10D 64/27; H10D 84/01

(52) U.S. Cl. CPC H10D 84/141; H10D 30/015; H10D 30/0295; H10D 30/0297; H10D 30/475; H10D 30/478; H10D 30/665; H10D 30/668; H10D 62/103; H10D 62/124; H10D 64/514; H10D 64/518; H10D 84/0123; H10D 64/111

(57) ABSTRACT

A nitride semiconductor device includes: a substrate; a first semiconductor layer of a first conductivity type disposed above the substrate; a second semiconductor layer of a second conductivity type disposed above the first semiconductor layer; a third semiconductor layer that includes a channel and is at least partially disposed above the second semiconductor layer; a gate electrode; a source electrode; a drain electrode; a first insulating layer disposed above the gate electrode and including nitride as a main component; and a second insulating layer disposed to cover a side surface of a groove that is provided in an edge termination area of the nitride semiconductor device. In the plan view, an end portion of the first insulating layer coincides with an end portion of the groove, or is positioned inside relative to the end portion of the groove and outside relative to an outermost periphery of the source electrode.

### CROSS REFERENCE TO RELATED APPLICATIONS

This is a continuation application of PCT International Application No. PCT/JP2023/039964 filed on Nov. 7, 2023, designating the United States of America, which is based on and claims priority of Japanese Patent Application No. 2022-192577 filed on Dec. 1, 2022. The entire disclosures of the above-identified applications, including the specifications, drawings and claims are incorporated herein by reference in their entirety.

### FIELD

The present disclosure relates to a nitride semiconductor device and a method for manufacturing the nitride semiconductor device.

### BACKGROUND

Nitride semiconductors, represented by gallium nitride (GaN), are wide-gap semiconductors that have a large bandgap, have a high dielectric breakdown electric field strength, and have a higher saturated drift velocity of electrons than compound semiconductors, such as gallium arsenide (GaAs), or silicon (Si) semiconductors. For example, the bandgaps of GaN and AlN (aluminum nitride) are 3.4 eV and 6.2 eV at room temperature, respectively. Hence, research and development of power transistors using nitride semiconductors which are advantageous for high voltage resistance and high output have been actively conducted.

For example, Patent Literature (PTL) 1 discloses a vertical field effect transistor (FET) that includes GaN-based semiconductor layers.

### CITATION LIST

### Patent Literature

PTL 1: International Publication No. WO2022/176455

### SUMMARY

### Technical Problem

The nitride semiconductor device disclosed in PTL 1 has a problem in that the device may not be turned on properly under specific device driving conditions, leading to a low operation reliability. There is also a problem in the off characteristics that leakage current increases in an off state

In view of the above, the present disclosure provides a nitride semiconductor device that has a high operation reliability and improved off characteristics, and a method for manufacturing the nitride semiconductor device.

### Solution to Problem

A nitride semiconductor device according to one aspect of the present disclosure includes: a substrate; a first semiconductor layer of a first conductivity type that is disposed above the substrate; a second semiconductor layer of a second conductivity type that is disposed above the first semiconductor layer; a third semiconductor layer that includes a channel and is at least partially disposed above the second semiconductor layer; a gate electrode that is disposed above the first semiconductor layer; a source electrode that is spaced apart from the gate electrode; a drain electrode that is disposed below the substrate; a first insulating layer that is disposed above the gate electrode and includes nitride as a main component; and a second insulating layer that is disposed to cover a side surface of a groove that is provided in an edge termination area of the nitride semiconductor device, the groove penetrating through the first insulating layer and the second semiconductor layer to reach the first semiconductor layer. In a plan view, an end portion of the first insulating layer coincides with an end portion of the groove, or is positioned inside relative to the end portion of the groove and outside relative to an outermost periphery of the source electrode.

In a method for manufacturing a nitride semiconductor device according to one aspect of the present disclosure, the nitride semiconductor device includes: a substrate; a first semiconductor layer of a first conductivity type that is disposed above the substrate; a second semiconductor layer of a second conductivity type that is disposed above the first semiconductor layer; a third semiconductor layer that includes a channel and is at least partially disposed above the second semiconductor layer; a gate electrode that is disposed above the first semiconductor layer; a source electrode that is spaced apart from the gate electrode; and a drain electrode that is disposed below the substrate. The method for manufacturing the nitride semiconductor device includes: forming, above the gate electrode, a first insulating layer that includes nitride as a main component; forming a groove in an edge termination area of the nitride semiconductor device, the groove penetrating through the first insulating layer and the second semiconductor layer to reach the first semiconductor layer; and forming a second insulating layer to cover a side surface of the groove. In a plan view, an end portion of the first insulating layer coincides with an end portion of the groove, or is positioned inside relative to the end portion of the groove and outside relative to an outermost periphery of the source electrode.

### Advantageous Effects

According to the present disclosure, it is possible to provide a nitride semiconductor device that has a high operation reliability and improved off characteristics, and a method for manufacturing the nitride semiconductor device.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional view of a nitride semiconductor device according to Embodiment 1.

FIG. 2 is a plan view of the nitride semiconductor device according to Embodiment 1.

FIG. 3 is a flowchart of a method for manufacturing the nitride semiconductor device according to Embodiment 1.

FIG. 4 is a cross-sectional view of a nitride semiconductor device according to Embodiment 2.

FIG. 5 is a flowchart of the method for manufacturing the nitride semiconductor device according to Embodiment 2.

FIG. 6 is a cross-sectional view of a nitride semiconductor device according to Variation 1.

FIG. 7 is a cross-sectional view of a nitride semiconductor device according to Variation 2.

FIG. 8 is a cross-sectional view of a nitride semiconductor device according to Variation 3.

FIG. 9 is a cross-sectional view of a nitride semiconductor device according to Variation 4.

FIG. 10 is a cross-sectional view of a nitride semiconductor device according to Variation 5.

### DESCRIPTION OF EMBODIMENTS

### Underlying Knowledge Forming Basis of the Present Disclosure

The inventors have found that the following problems arise with the conventional nitride semiconductor devices described in the “Background” section.

An insulating layer is disposed between the gate electrode and the field plate in the transistor area of the nitride semiconductor device disclosed in PTL 1. In the edge termination area of the nitride semiconductor device, portions of the p type semiconductor layer and the n type semiconductor layer are removed, so that the side portion of the p-n junction interface is exposed. An insulating layer is disposed to cover the surface of the n type semiconductor layer and the side portion of the p-n junction interface that are exposed. The insulating layer in the transistor area and the insulating layer in the edge termination area are formed simultaneously. For example, a silicon nitride (SiN) film formed by plasma chemical vapor deposition (CVD) or a silicon oxide (SiO₂) film formed by spin coating are used for the insulating layers.

However, when a deposition method, such as plasma CVD, which damages the surface of the semiconductor layer is used, the exposed side portion of the p-n junction interface degrades. This results in a problem in the off characteristics in which leakage current increases in an off state.

On the other hand, spin coating is available as a deposition method that causes little damage to the semiconductor layer. The spin coating is used, for example, to form SiO₂ films. However, the SiO₂ films formed by the spin coating are highly amorphous, and easily generate unintended charge in the films. In the transistor area of a nitride semiconductor device, the presence of an insulating layer in which charge is generated between the field plate connected to the source electrode and the gate electrode makes it difficult to perform proper application of the gate potential. As a result, switching problems arise, such as the device not turning on properly depending on the device driving conditions.

As described above, in conventional nitride semiconductor devices, it is difficult to inhibit both an increase in leakage current and the switching problems. In view of the above, the present disclosure provides a nitride semiconductor device that has improved off characteristics that are achieved by inhibiting an increase in leakage current, and has a high operation reliability that is achieved by inhibiting the switching problems, and a method for manufacturing the nitride semiconductor device.

Examples of the nitride semiconductor device and the method for manufacturing the nitride semiconductor device according to the present disclosure will be described below.

A nitride semiconductor device according to a first aspect of the present disclosure includes: a substrate; a first semiconductor layer of a first conductivity type that is disposed above the substrate; a second semiconductor layer of a second conductivity type that is disposed above the first semiconductor layer; a third semiconductor layer that includes a channel and is at least partially disposed above the second semiconductor layer; a gate electrode that is disposed above the first semiconductor layer; a source electrode that is spaced apart from the gate electrode; a drain electrode that is disposed below the substrate; a first insulating layer that is disposed above the gate electrode and includes nitride as a main component; and a second insulating layer that is disposed to cover a side surface of a groove that is provided in an edge termination area of the nitride semiconductor device, the groove penetrating through the first insulating layer and the second semiconductor layer to reach the first semiconductor layer. In a plan view, an end portion of the first insulating layer coincides with an end portion of the groove, or is positioned inside relative to the end portion of the groove and outside relative to an outermost periphery of the source electrode.

With this, the high crystallinity of the first insulating layer, which includes nitride as a main component, inhibits the generation of charge in the film. Therefore, degradation of the switching characteristics can be inhibited and the operation reliability can be improved. Moreover, after the formation of the first insulating layer, the groove in the edge termination area can be formed. This inhibits damage to the p-n junction interface exposed to the groove when the first dielectric film is formed. Therefore, the leakage current in an off state in the edge termination area can be inhibited, thus improving the off characteristics. In this way, according to the present aspect, it is possible to achieve a nitride semiconductor device that has a high operation reliability and improved off characteristics.

Moreover, the nitride semiconductor device according to a second aspect of the present disclosure, for example, in the nitride semiconductor device according to the first aspect, further includes: a fourth semiconductor layer that is disposed above the second semiconductor layer. The third semiconductor layer includes a plurality of semiconductor films having different bandgaps, the channel is two-dimensional electron gas generated at an interface between adjacent ones of the plurality of semiconductor films, the gate electrode overlaps, in the plan view, a first opening that penetrates through the fourth semiconductor layer and the second semiconductor layer to reach the first semiconductor layer, and a portion of the third semiconductor layer is disposed along an inner surface of the first opening between the inner surface of the first opening and the gate electrode.

With this, it is possible to achieve a vertical nitride semiconductor device that has a high operation reliability and improved off characteristics.

Moreover, the nitride semiconductor device according to a third aspect of the present disclosure, for example, in the nitride semiconductor device according to the second aspect, further includes: a fifth semiconductor layer of the second conductivity type that is disposed between the third semiconductor layer and the gate electrode.

With this, the potential at the conduction band edge of the channel portion can be raised and the threshold voltage can be increased. Therefore, for example, it is possible to achieve a normally-off FET.

Moreover, in the nitride semiconductor device according to a fourth aspect of the present disclosure, for example, in the nitride semiconductor device according to the first aspect, the gate electrode overlaps, in the plan view, a first opening that penetrates through the third semiconductor layer and the second semiconductor layer to reach the first semiconductor layer. The nitride semiconductor device further includes: a gate insulating layer that is disposed along an inner surface of the first opening between the inner surface of the first opening and the gate electrode.

With this, it is possible to achieve a nitride semiconductor device that has a recessed MISFET structure in which the operation reliability is high and the off characteristics are improved.

Moreover, in the nitride semiconductor device according to a fifth aspect of the present disclosure, for example, in the nitride semiconductor device according to any one of the first aspect to the fourth aspect, the first insulating layer has a substantially uniform thickness.

With this, for example, it is possible to form a first insulating layer having a uniform thickness and high crystallinity by plasma CVD or the like. In addition, the thickness of the first insulating layer can be easily increased, leading to a further increase in the reliability of the nitride semiconductor device.

Moreover, in the nitride semiconductor device according to a sixth aspect of the present disclosure, for example, in the nitride semiconductor device according to any one of the first aspect to the fifth aspect, the second insulating layer is disposed above the first insulating layer and overlaps the gate electrode in the plan view.

This allows the thickness of the insulating layer in the operating region as a transistor to be increased, leading to a further increase in the reliability of the nitride semiconductor device.

Moreover, in the nitride semiconductor device according to a seventh aspect of the present disclosure, for example, in the nitride semiconductor device according to the sixth aspect, a thickness of a portion of the second insulating layer that is disposed in the groove is different from a thickness of a portion of the second insulating layer that overlaps the gate electrode in the plan view.

This allows the second insulating layer to be formed by, for example, a method, such as spin-coating, that causes little damage to the p-n junction interface. Hence, it is possible to inhibit leakage current in an off state, leading to improved off characteristics.

Moreover, in the nitride semiconductor device according to an eighth aspect of the present disclosure, for example, in the nitride semiconductor device according to any one of the first aspect to the seventh aspect, the first insulating layer has a monolayer structure of SiN or a stacked structure in which a lowermost layer is a SiN layer.

With this, the use of highly crystalline SiN inhibits the degradation of the switching characteristics, leading to an increase in the reliability of the nitride semiconductor device.

Moreover, in the nitride semiconductor device according to a ninth aspect of the present disclosure, for example, in the nitride semiconductor device according to the first aspect, the second insulating layer has a monolayer structure or a stacked structure each of which includes a film selected from a group including SiN, SiO₂, HfO₂, Al₂O₃, ZrO₂, AlN, HfON, and ZrON.

With this, for example, it is possible to easily form the second insulating layer by, for example, spin coating.

Moreover, the nitride semiconductor device according to a tenth aspect of the present disclosure, for example, in the nitride semiconductor device according to any one of the first aspect to the ninth aspect, further includes: source wiring that is disposed above the first insulating layer and penetrates through the first insulating layer to be connected to the source electrode; and a third insulating layer that is disposed above the source wiring.

With this, the source wiring is also capable of functioning as a field plate. This alleviates the concentration of the electric field in the edge termination area, leading to improved off characteristics.

Moreover, in a method for manufacturing a nitride semiconductor device according to an eleventh aspect of the present disclosure, for example, the nitride semiconductor device includes: a substrate; a first semiconductor layer of a first conductivity type that is disposed above the substrate; a second semiconductor layer of a second conductivity type that is disposed above the first semiconductor layer; a third semiconductor layer that includes a channel and is at least partially disposed above the second semiconductor layer; a gate electrode that is disposed above the first semiconductor layer; a source electrode that is spaced apart from the gate electrode; and a drain electrode that is disposed below the substrate. The method for manufacturing the nitride semiconductor device includes: forming, above the gate electrode, a first insulating layer that includes nitride as a main component; forming a groove in an edge termination area of the nitride semiconductor device, the groove penetrating through the first insulating layer and the second semiconductor layer to reach the first semiconductor layer; and forming a second insulating layer to cover a side surface of the groove. In a plan view, an end portion of the first insulating layer coincides with an end portion of the groove, or is positioned inside relative to the end portion of the groove and outside relative to an outermost periphery of the source electrode.

With this, the high crystallinity of the first insulating layer, which includes nitride as a main component, inhibits the generation of charge in the film. Hence, it is possible to inhibit the degradation of the switching characteristics, leading to an increase in the reliability of the operation. Moreover, the groove in the edge termination area is formed after the formation of the first insulating layer. This inhibits damage to the p-n junction interface exposed to the groove when the first insulating layer is formed. Hence, it is possible to inhibit leakage current in the edge termination area in an off state, leading to improved off characteristics. In this way, it is possible to manufacture a nitride semiconductor device that has a high operation reliability and improved off characteristics.

Moreover, in the method for manufacturing the nitride semiconductor device according to a twelfth aspect of the present disclosure, for example, in the method for manufacturing the nitride semiconductor device according to the eleventh aspect, in the forming of the first insulating layer, the first insulating layer is formed by plasma chemical vapor deposition (CVD).

With this, it is possible to form the first insulating layer having high crystallinity, inhibiting the degradation of the switching characteristics.

Moreover, in the method for manufacturing the nitride semiconductor device according to a thirteenth aspect of the present disclosure, for example, in the method for manufacturing the nitride semiconductor device according to the eleventh aspect or the twelfth aspect, in the forming of the second insulating layer, the second insulating layer is formed by spin coating.

With this, since damage to the p-n junction interface exposed to the side surface of the groove is less likely to occur, it is possible to inhibit leakage current in an off, leading to improved off characteristics.

Embodiments will be specifically described below with reference to drawings.

Each of the embodiments described below shows a general or specific example. Numerical values, shapes, materials, structural elements, the arrangement and connection of the structural elements, steps, the order of the steps, and the like shown in the following embodiments are examples, and are not intended to limit the present disclosure. Among the structural elements in the following embodiments, structural elements which are not recited in the independent claim are described as optional structural elements.

The drawings are schematic views and are not exactly Hence, for example, scales and the like are not illustrated. necessarily the same in the drawings. In the drawings, substantially the same configurations are identified with the same reference signs, and repeated descriptions are omitted or simplified.

In the present description, terms such as parallel and orthogonal which indicate relationships between elements, terms such as rectangular and trapezoid which indicate the shapes of elements, and numerical ranges are expressions which not only indicate exact meanings but also indicate substantially equivalent ranges such as a range including a several percent difference.

In the present description and the drawings, an x-axis, a y-axis, and a z-axis indicate three axes of a three-dimensional orthogonal coordinate system. When the shape of a substrate in plan view is a rectangle, the x-axis and the y-axis respectively extend in a direction parallel to a first side of the rectangle and in a direction parallel to a second side orthogonal to the first side. The z-axis extends in the direction of thickness of the substrate. In the present description, the “direction of thickness” of the substrate refers to a direction perpendicular to the main surface of the substrate. The direction of thickness is the same as the stacking direction of semiconductor layers, and is also referred to as a “longitudinal direction”. A direction parallel to the main surface of the substrate may be referred to as a “lateral direction”.

The side (the positive side of the z-axis) on which a gate electrode and a source electrode are disposed with respect to the substrate is regarded as being “above” or “upper side”, and the side (the negative side of the z-axis) on which a drain electrode is disposed with respect to the substrate is regarded as being “below” or a “lower side”.

In the present description, terms of “above” and “below” do not indicate an upward direction (vertically upward) and a downward direction (vertically downward) in absolute spatial recognition, but are used as terms for defining a relative positional relationship based on a stacking order in a stacked structure. The terms of “above” and “below” are applied not only to a case where two structural elements are spaced with another structural element present between the two structural elements, but also to a case where two structural elements are closely arranged and in contact with each other.

In the present description, “in plan view” means that the main surface of the substrate of a nitride semiconductor device is viewed in a direction perpendicular to the main surface, that is, that the main surface of the substrate is viewed from the front.

In the present description, unless otherwise specified, ordinal numbers such as “first” and “second” do not mean the number or order of structural elements but are used to avoid confusion of similar structural elements and to distinguish between them. In the present description, AlGaN indicates a ternary mixed crystal of AlₓGa₁₋ₓN (0<x<1). In the following description, multinary mixed crystals are abbreviated by the sequences of structural element symbols such as AlInN and GaInN. For example, AlₓGa_{1-x-y}In_{y}N (0<x<1, 0<y<1, and 0<x+y<1) which is an example of a nitride semiconductor is abbreviated as AlGaInN.

### Embodiment 1

### Outline

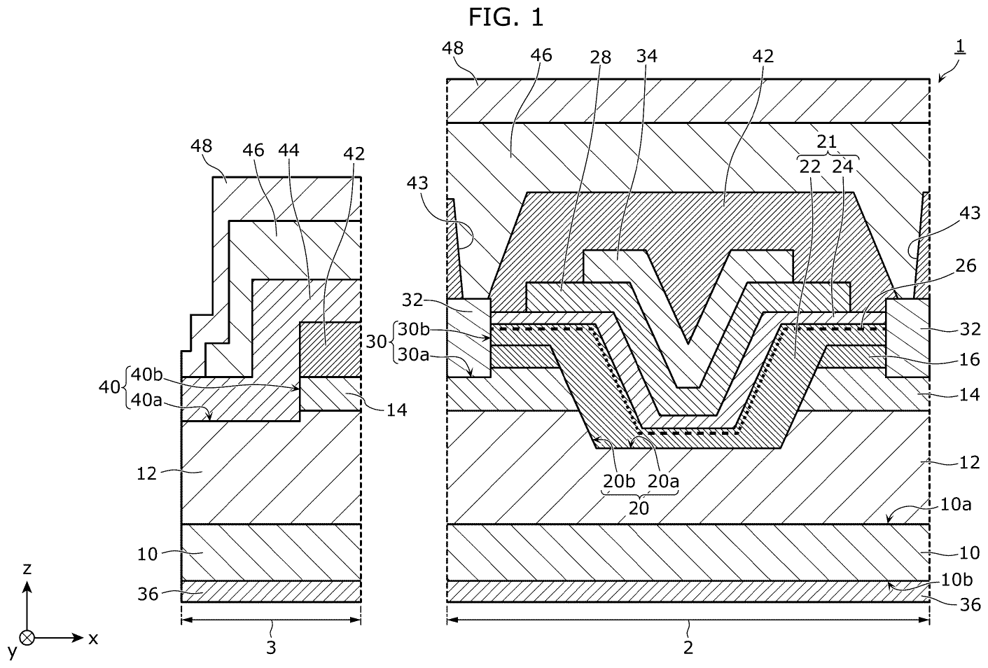

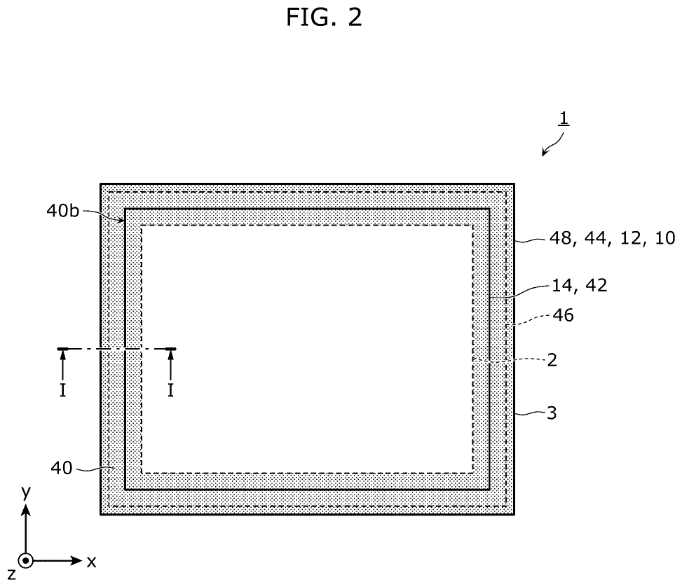

First, an outline of a nitride semiconductor device according to Embodiment 1 will be described with reference to FIG. 1 and FIG. 2.

FIG. 1 is a cross-sectional view of nitride semiconductor device 1 according to the present embodiment. FIG. 2 is a plan view of nitride semiconductor device 1 according to the present embodiment. FIG. 1 illustrates a cross-section taken along line I-I in FIG. 2. In FIG. 1, a portion between transistor area 2 and edge termination area 3 is schematically illustrated such that transistor area 2 and edge termination area 3 are separated.

As illustrated in FIG. 1, nitride semiconductor device 1 includes transistor area 2 and edge termination area 3. Specifically, nitride semiconductor device 1 includes substrate 10, drift layer 12, first base layer 14, second base layer 16, gate opening 20, semiconductor multilayer film 21, threshold adjustment layer 28, source opening 30, source electrode 32, gate electrode 34, drain electrode 36, first insulating layer 42, second insulating layer 44, source wiring 46, and third insulating layer 48. Semiconductor multilayer film 21 is a stack of electron transport layer 22 and electron supply layer 24, and includes two-dimensional electron gas (2DEG) 26 as a channel region. Nitride semiconductor device 1 also includes groove 40 provided in edge termination area 3.

Transistor area 2 is a region that includes a FET, and also includes the central portion of nitride semiconductor device 1, as illustrated in FIG. 2. Transistor area 2 serves as a current path between the source and the drain in an on state. Specifically, transistor area 2 is a region in which second base layer 16, gate opening 20, semiconductor multilayer film 21, threshold adjustment layer 28, source electrode 32, and gate electrode 34 are disposed in plan view.

In FIG. 2, illustration of each structural element arranged in transistor area 2 is omitted. As an example, a plurality of source electrodes 32 elongated in one direction in plan view are arranged in stripes, and gate electrode 34, threshold adjustment layer 28, and gate opening 20 are arranged between adjacent source electrodes 32. Alternatively, a plurality of source electrodes 32 that are hexagonal in plan view may be arranged to be spaced to fill a plane.

Edge termination area 3 is a region other than transistor area 2, and is provided in a ring shape to surround transistor area 2. Edge termination area 3 is a portion that does not serve as the current path between the source and the drain in an on state. Edge termination area 3 can be regarded as the region outside relative to the outermost periphery of source electrode 32. Second base layer 16, gate opening 20, semiconductor multilayer film 21, threshold adjustment layer 28, source electrode 32, and gate electrode 34 are not disposed in edge termination area 3. Second base layer 16, semiconductor multilayer film 21, and threshold adjustment layer 28 may be disposed in edge termination area 3 as long as second base layer 16, semiconductor multilayer film 21, and threshold adjustment layer 28 are electrically separated from source electrode 32. In this case, too, groove 40 reaches at least drift layer 12.

In the present embodiment, nitride semiconductor device 1 includes a stacked structure of semiconductor layers that include, as a main component, nitride semiconductors, such as GaN and AlGaN. The phrase “A includes B as a main component” means that the content of B in A is at least 50%.

Specifically, nitride semiconductor device 1 includes a heterostructure of AlGaN and GaN films. In the heterostructure of the AlGaN and GaN films, high-concentration two-dimensional electron gas 26 is generated at the heterointerface by spontaneous polarization or piezoelectric polarization on a (0001) plane. Hence, even in an undoped state, a sheet carrier concentration of at least 1×10¹³ cm⁻² can be obtained at the interface.

Nitride semiconductor device 1 according to the present embodiment is a field-effect transistor (FET) that uses, as a channel, two-dimensional electron gas 26 generated at the heterointerface of AlGaN/GaN. Specifically, nitride semiconductor device 1 is a so-called vertical FET.

Nitride semiconductor device 1 according to the present embodiment is a normally-off FET. In nitride semiconductor device 1, for example, source electrode 32 is grounded (i.e., the potential is 0 V) and a positive potential is applied to drain electrode 36. Although the potential applied to drain electrode 36 is, for example, at least 100 V and at most 1200 V, the potential is not limited to such an example. When nitride semiconductor device 1 is in an off state, 0 V or a negative potential (e.g., −5 V) is applied to gate electrode 34. When nitride semiconductor device 1 is in an on state, a positive potential (e.g., +5 V) is applied to gate electrode 34. Nitride semiconductor device 1 may be a normally-on FET.

### Configuration

Each structural element included in nitride semiconductor device 1 will be described below in detail.

Substrate 10 is a substrate of nitride semiconductors, and includes, as illustrated in FIG. 1, first main surface 10a and second main surface 10b that face away from each other. First main surface 10a is the main surface (top surface) on the side on which drift layer 12 is disposed. Specifically, first main surface 10a substantially coincides with a c-plane. Second main surface 10b is the main surface (bottom surface) on the side on which drain electrode 36 is disposed. Although the plan view shape of substrate 10 is, for example, a rectangle, the shape is not limited to the rectangle.

Substrate 10 is, for example, a substrate including n+type GaN and having a thickness of 300 um and a carrier concentration of 1×10¹⁸ cm⁻³. The n type and p type each indicate the conductivity type of a semiconductor. The n⁺ type indicates a state in which a high concentration of n type dopant is added into a semiconductor, that is, a so-called heavily doped state. The n⁻ type indicates a state in which a low concentration of n type dopant is added into a semiconductor, that is, a so-called lightly doped state. The same is true for the p⁺ type and p⁻ type. The n type, the n⁺ type and the n type are examples of a first conductivity type. The p type, the p⁺ type, and the p⁻ type are examples of a second conductivity type. The second conductivity type is the opposite polarity conductivity type of the first conductivity type.

Substrate 10 does not have to be a nitride semiconductor substrate. For example, substrate 10 may be a silicon (Si) substrate, silicon carbide (SiC) substrate, or zinc oxide (ZnO) substrate.

Drift layer 12 is an example of a first nitride semiconductor layer of the first conductivity type disposed above substrate 10. Drift layer 12 is, for example, a film including n type GaN and having a thickness of 8 μm. The donor concentration of drift layer 12 is, for example, in a range from at least 1×10¹⁵ cm⁻³ to at most 1×10¹⁷cm⁻³, and is, for example, 1×10¹⁶ cm⁻³. For example, the carbon concentration (C concentration) of drift layer 12 is in a range from at least 1×10¹⁵ cm⁻³ to at most 2×10¹⁷ cm⁻³.

Drift layer 12 is, for example, in contact with first main surface 10a of substrate 10. Drift layer 12 is formed on first main surface 10a of substrate 10 by crystal growth such as metal organic vapor phase epitaxy (MOVPE) or hydride vapor phase epitaxy (HVPE).

First base layer 14 is an example of a second nitride semiconductor layer of a second conductivity type that is disposed above drift layer 12. First base layer 14 is, for example, a film including p type GaN and having a thickness of 400 nm and a carrier concentration of 1×10¹⁷ cm⁻³. First base layer 14 is in contact with the top surface of drift layer 12. First base layer 14 is formed on drift layer 12 by crystal growth such as MOVPE or HVPE. First base layer 14 may be formed by implanting magnesium (Mg) into the undoped GaN film. The term “undoped” will be described later.

First base layer 14 inhibits leakage current between source electrode 32 and drain electrode 36. For example, when a reverse voltage is applied to the p-n junction formed by first base layer 14 and drift layer 12, specifically, when the potential of drain electrode 36 is higher than the potential of source electrode 32, a depletion layer extends to drift layer 12. This allows nitride semiconductor device 1 to have a high voltage resistance. In the present embodiment, the potential of drain electrode 36 is higher than the potential of source electrode 32 both in an off state and in an on state, except in the case of a reverse conduction operation. Therefore, it is possible to increase the voltage resistance of nitride semiconductor device 1.

In the present embodiment, as illustrated in FIG. 1, first base layer 14 is in contact with source electrode 32. Therefore, first base layer 14 is fixed at the same potential as source electrode 32.

Second base layer 16 is an example of a fourth nitride semiconductor layer disposed above first base layer 14. Second base layer 16 is a high-resistance layer that has a resistance higher than the resistance of first base layer 14. Second base layer 16 includes an insulating or semi-insulating nitride semiconductor. Second base layer 16 is, for example, a film including undoped GaN and having a thickness of 200 nm. Second base layer 16 is in contact with first base layer 14. Second base layer 16 is formed on first base layer 14 by crystal growth such as MOVPE or HVPE.

Here, the term “undoped” means that GaN is not doped with a dopant, such as Si or Mg that changes the polarity of GaN to the n type or the p type. In the present embodiment, second base layer 16 is doped with carbon (C). Specifically, the carbon concentration of second base layer 16 is higher than the carbon concentration of first base layer 14.

Second base layer 16 may include silicon (Si) or oxygen (O) that is introduced during deposition. In this case, the carbon concentration of second base layer 16 is higher than the silicon concentration (Si concentration) or oxygen concentration (O concentration). For example, the carbon concentration of second base layer 16 is, for example, at least 3×10¹⁷ cm⁻³, but may be at least 1×10₁₈ cm⁻³. The silicon concentration or oxygen concentration of second base layer 16 is, for example, at most 5×10₁₆ cm⁻³, but may be at most 2×10₁₆ cm⁻³.

Second base layer 16 may be formed by ion implantation of magnesium (Mg), iron (Fe), or boron (B) other than carbon. Other ion species may be used as long as they can achieve high resistance of GaN.

Here, when nitride semiconductor device 1 does not include second base layer 16, a parasitic npn structure that is a parasitic bipolar transistor, which includes electron transport layer 22, p type first base layer 14, and n type drift layer 12, is present between source electrode 32 and drain electrode 36. Therefore, when current flows through p type first base layer 14 while nitride semiconductor device 1 is in an off state, the parasitic bipolar transistor is turned on, which may reduce the voltage resistance of nitride semiconductor device 1. In this case, nitride semiconductor device 1 is prone to a malfunction. In the present embodiment, high-resistance second base layer 16 inhibits the formation of the parasitic npn structure, and prevents malfunctions in nitride semiconductor device 1.

Second base layer 16 may be disposed below first base layer 14 and between first base layer 14 and drift layer 12. Alternatively, second base layers 16 may be disposed both above and below first base layer 14.

A layer may be disposed on the top surface of second base layer 16 to inhibit the diffusion of p type impurities such as Mg from first base layer 14. For example, an AlGaN layer having a thickness of 20 nm may be disposed on second base layer 16.

Gate opening 20 is an example of a first opening that penetrates through first base layer 14 to reach drift layer 12. Gate opening 20 penetrates through both second base layer 16 and first base layer 14. Bottom 20a of gate opening 20 is a portion of the top surface of drift layer 12. As illustrated in FIG. 1, bottom 20a is positioned below the bottom surface of first base layer 14. The bottom surface of first base layer 14 corresponds to the interface between first base layer 14 and drift layer 12. Bottom 20a is parallel to, for example, first main surface 10a of substrate 10.

In the present embodiment, the opening area of gate opening 20 increases as the distance from substrate 10 increases. Specifically, each side wall 20b of gate opening 20 is inclined at an angle. As illustrated in FIG. 1, the cross-sectional shape of gate opening 20 is an inverted trapezoid, or more specifically, is an inverted isosceles trapezoid.

The angle of inclination of side wall 20b with respect to bottom 20a is, for example, in a range from at least 30° to at most 45°. With a decrease in the angle of inclination, the distance between side wall 20b and the c-plane decreases. This increases the film quality of electron transport layer 22 and the like formed along side wall 20b by crystal regrowth. On the other hand, with an increase in the angle of inclination, an excessive increase in the size of gate opening 20 is inhibited, leading to a reduction in size of nitride semiconductor device 1.

Semiconductor multilayer film 21 is an example of a third nitride semiconductor layer that includes a channel, and is at least partially disposed above first base layer 14. Specifically, semiconductor multilayer film 21 includes a plurality of semiconductor films having different bandgaps. Two-dimensional electron gas 26 that is generated at the interface between adjacent ones of the semiconductor films serves as a channel. The term “channel” means at least a portion of the current path between the source and the drain.

In the present embodiment, a portion of semiconductor multilayer film 21 is disposed along the inner surface of gate opening 20 between the inner surface of gate opening 20 and gate electrode 34. Another portion of semiconductor multilayer film 21 is disposed above second base layer 16. Semiconductor multilayer film 21 is a stacked film of electron transport layer 22 and electron supply layer 24. Electron transport layer 22 and electron supply layer 24 are examples of a plurality of semiconductor films having different bandgaps.

Electron transport layer 22 is an example of a first regrown layer disposed along the inner surface of gate opening 20. Specifically, a portion of electron transport layer 22 is disposed along bottom 20a and side walls 20b of gate opening 20, and the other portions of electron transport layer 22 are disposed on the top surface of second base layer 16. Electron transport layer 22 is, for example, a film including undoped GaN and having a thickness of 150 nm. Electron transport layer 22 may be not undoped, but doped with Si or the like to be n type electron transport layer 22.

Electron transport layer 22 is in contact with drift layer 12 at bottom 20a and side walls 20b of gate opening 20. Electron transport layer 22 is in contact with the end surfaces of first base layer 14 and second base layer 16 at side walls 20b of gate opening 20. Electron transport layer 22 is also in contact with the top surface of second base layer 16. Electron transport layer 22 is formed by crystal regrowth after gate opening 20 is formed.

Electron transport layer 22 includes a channel region. Specifically, two-dimensional electron gas 26 is generated in the vicinity of the interface between electron transport layer 22 and electron supply layer 24. Two-dimensional electron gas 26 serves as a channel in electron transport layer 22. In FIG. 1, two-dimensional electron gas 26 is schematically illustrated by dashed lines. Two-dimensional electron gas 26 is bent along the interface between electron transport layer 22 and electron supply layer 24, i.e., along the inner surface of gate opening 20.

Moreover, although not illustrated in FIG. 1, an AlN film having a thickness of approximately 1 nm may be disposed as a second regrown layer between electron transport layer 22 and electron supply layer 24. The AlN film inhibits alloy scattering and increases the mobility of the channel.

Electron supply layer 24 is an example of a third regrown layer disposed along the inner surface of gate opening 20. Electron transport layer 22 and electron supply layer 24 are disposed in this order from substrate 10 side. Electron supply layer 24 is formed along the top surface of electron transport layer 22 to have a substantially uniform thickness. Electron supply layer 24 is, for example, a film including undoped AlGaN and having a thickness of 50 nm. Electron supply layer 24 is formed by crystal regrowth, following the formation of electron transport layer 22.

Electron supply layer 24 has a bandgap larger than the bandgap of electron transport layer 22. Therefore, a heterointerface of AlGaN/GaN is formed between electron supply layer 24 and electron transport layer 22. This generates two-dimensional electron gas 26 in electron transport layer 22. Electron supply layer 24 supplies electrons to the channel region (i.e., two-dimensional electron gas 26) formed in electron transport layer 22.

Threshold adjustment layer 28 is an example of a fourth nitride semiconductor layer of the second conductivity type disposed between semiconductor multilayer film 21 and gate electrode 34. Specifically, threshold adjustment layer 28 is disposed between gate electrode 34 and electron supply layer 24. Threshold adjustment layer 28 is formed along the top surface of electron supply layer 24 to have a substantially uniform thickness.

Threshold adjustment layer 28 is, for example, a nitride semiconductor layer including p type GaN or AlGaN, and having a thickness of 100 nm and a carrier concentration of 1×10¹⁷ cm⁻³. Threshold adjustment layer 28 is formed by regrowth in the MOVPE and HVPE and patterning, following the formation step of electron supply layer 24.

Threshold adjustment layer 28 is provided to raise the potential of the conduction band edge of the channel portion. Therefore, the threshold voltage of nitride semiconductor device 1 can be increased. Accordingly, nitride semiconductor device 1 can be implemented as a normally-off FET. In other words, nitride semiconductor device 1 can be turned off when a potential of 0 V is applied to gate electrode 34. Threshold adjustment layer 28 does not have to be disposed.

Source opening 30 is an example of a second opening that penetrates through semiconductor multilayer film 21 and second base layer 16 to reach first base layer 14 at a position distant from gate opening 20. Source opening 30 is positioned distant from gate electrode 34 in plan view.

Bottom 30a of source opening 30 serves as a portion of the top surface of first base layer 14. As illustrated in FIG. 1, bottom 30a is positioned below the bottom surface of second base layer 16. The bottom surface of second base layer 16 corresponds to the interface between second base layer 16 and first base layer 14. Bottom 30a is parallel to, for example, first main surface 10a of substrate 10.

As illustrated in FIG. 1, the opening area of source opening 30 is uniform regardless of the distance from substrate 10. Specifically, side wall 30b of source opening 30 is perpendicular to bottom 30a. In other words, the cross-sectional shape of source opening 30 is a rectangle.

Alternatively, in a similar manner to gate opening 20, the opening area of source opening 30 may increase as the distance from substrate 10 increases. Specifically, side wall 30b of source opening 30 may be inclined at an angle. For example, the cross-sectional shape of source opening 30 may be an inverted trapezoid, or more specifically, is an inverted isosceles trapezoid. Here, the angle of inclination of side wall 30b with respect to bottom 30a may be, for example, in a range from at least 30° to at most 60°. For example, the angle of inclination of side wall 30b of source opening 30 may be greater than the angle of inclination of side wall 20b of gate opening 20. Side wall 30b is inclined, and thus, the contact area between source electrode 32 and electron transport layer 22 (two-dimensional electron gas 26) is increased. This facilitates an ohmic connection. Two-dimensional electron gas 26 is exposed to side wall 30b of source opening 30, and is connected to source electrode 32 at the exposed portion.

Source electrode 32 is spaced apart from gate electrode 34. In the present embodiment, source electrode 32 is disposed along the inner surface of source opening 30. Specifically, source electrode 32 is connected to each of electron supply layer 24, electron transport layer 22, and first base layer 14. Source electrode 32 is ohmically connected to each of electron transport layer 22 and electron supply layer 24. Side wall 30b of source electrode 32 is in direct contact with two-dimensional electron gas 26. This reduces the contact resistance between source electrode 32 and two-dimensional electron gas 26 (channel).

Source electrode 32 is formed by using a conductive material, such as metal. Examples of the material of source electrode 32 include a material, such as Ti/Al, which is thermally processed to be ohmically connected to an n type GaN layer. Source electrode 32 is formed, for example, by patterning a conductive film formed by sputtering or vapor deposition.

Gate electrode 34 is disposed above threshold adjustment layer 28, and overlaps gate opening 20 in plan view. Specifically, gate electrode 34 is in contact with the top surface of threshold adjustment layer 28 to cover gate opening 20. Gate electrode 34, for example, is formed along the top surface of threshold adjustment layer 28 to have a substantially uniform thickness. Alternatively, gate electrode 34 may be formed to fill a recess on the top surface of threshold adjustment layer 28.

Gate electrode 34 is formed by using a conductive material, such as metal. For example, gate electrode 34 is formed by using palladium (Pd). Examples of the material of gate electrode 34 include a material that is ohmically connected to a p type GaN layer, such as a nickel (Ni)-based material, tungsten silicide (WSi), or gold (Au). Gate electrode 34 is formed, after the formation of threshold adjustment layer 28, source opening 30, or source electrode 32, for example, by patterning a conductive film formed by sputtering, vapor evaporation or the like.

Drain electrode 36 is disposed below substrate 10. Specifically, drain electrode 36 is disposed on the side opposite to drift layer 12. More specifically, drain electrode 36 is in contact with second main surface 10b of substrate 10. Drain electrode 36 is formed by using a conductive material, such as metal. Examples of the material of drain electrode 36 include, in a similar manner to the material of source electrode 32, a material, such as Ti/Al, which is ohmically connected to an n type GaN layer. Drain electrode 36 is formed, for example, by patterning a conductive film formed by sputtering, vapor evaporation, or the like.

### Characteristic Configuration

Main characteristic configurations of nitride semiconductor device 1 according to the present embodiment will be described below. First, a configuration of edge termination area 3 of nitride semiconductor device 1 will be described.

As illustrated in FIG. 1, in the present embodiment, second base layer 16, semiconductor multilayer film 21, and threshold adjustment layer 28 are not disposed in edge termination area 3. For example, second base layer 16, semiconductor multilayer film 21, and threshold adjustment layer 28 in edge termination area 3 are removed at the same time as the formation of source opening 30. In edge termination area 3, the top surface of first base layer 14 is positioned at the same height as bottom 30a of source opening 30. The phrase “at the same height” means that the distance from first main surface 10a of substrate 10 is the same.

Edge termination area 3 includes groove 40. Groove 40 is an isolation trench for partitioning and separating transistor area 2. Groove 40 penetrates through first insulating layer 42 and first base layer 14 to reach drift layer 12.

Groove 40 includes bottom 40a and side wall 40b. In the present embodiment, groove 40 is a recessed portion that includes side wall 40b only on the transistor area 2 side. In other words, bottom 40a of groove 40 is connected to the end surface of nitride semiconductor device 1. Groove 40 is provided in the shape of a ring surrounding transistor area 2, as illustrated in FIG. 2.

Bottom 40a of groove 40 is a portion of the top surface of drift layer 12. As illustrated in FIG. 1, bottom 40a is positioned below the bottom surface of first base layer 14. Bottom 40a is parallel to, for example, first main surface 10a of substrate 10.

Groove 40 may reach substrate 10. In other words, bottom 40a of groove 40 may serve as first main surface 10a of substrate 10. Leakage current can be further reduced by maximizing the depth of groove 40.

First insulating layer 42 is disposed above gate electrode 34. Specifically, first insulating layer 42 almost entirely covers transistor area 2, and includes an end portion that is positioned in edge termination area 3. First insulating layer 42 includes contact hole 43 for exposing source electrode 32. First insulating layer 42 contacts and covers each of gate electrode 34, threshold adjustment layer 28, and electron supply layer 24. First insulating layer 42 is disposed so as not to expose the electrodes and semiconductor layers other than source electrode 32 exposed to contact hole 43.

The end portion of first insulating layer 42 coincides with the end portion of groove 40 in plan view. As illustrated in FIG. 1, in cross-sectional view, the end portion (end surface) of first insulating layer 42 and the end portion (end surface) of first base layer 14 are continuous and form side wall 40b of groove 40. In other words, the end portion of first insulating layer 42 and the end portion of first base layer 14 do not form a level difference. In other words, the top surface of first base layer 14 is completely covered by first insulating layer 42. First insulating layer 42 does not cover the end surface of first base layer 14.

First insulating layer 42 includes nitride as a main component. Specifically, first insulating layer 42 is, for example, an insulating layer formed by the plasma CVD and including nitride that is an inorganic material as a main component. For example, first insulating layer 42 has a monolayer structure of SiN (silicon nitride). SiN is highly crystalline, and is capable of inhibiting unintended generation of charge in the film. Therefore, it is possible to inhibit the phenomenon in which switching is not properly performed under specific driving conditions, which is one of the problems to be solved. Thus, the reliability of the operation of nitride semiconductor device 1 can be increased.

The thickness of first insulating layer 42 formed by the plasma CVD is substantially uniform. The term “substantially uniform” means that variations in film thickness depending on the site are sufficiently small. For example, when the film thickness is measured at 10 different locations, the difference between the measurement value and the average value is at most ±10%.

Second insulating layer 44 is disposed so as to cover the side surface of groove 40 in edge termination area 3. The side surface of groove 40 (specifically, side wall 40b) exposes the interface between n type drift layer 12 and p type first base layer 14, i.e., the end portion of the p-n junction interface. The p-n junction interface is exposed when groove 40 is formed. Second insulating layer 44 covers the p-n junction interface exposed to side wall 40b of groove 40.

Second insulating layer 44 is disposed above first insulating layer 42 in edge termination area 3. Specifically, second insulating layer 44 is in contact with and covers the end surface and the top surface of first insulating layer 42.

Second insulating layer 44 has a monolayer structure including a film selected from the group including SiN, SiO₂, HfO₂ , Al₂O₃, ZrO₂ , AlN, HfON and ZrON. Second insulating layer 44 is formed by a method that causes little damage to the semiconductor surface, such as atomic layer deposition (ALD). This inhibits damages to the p-n junction interface of side wall 40b of groove 40. The thickness of second insulating layer 44 formed by the ALD is substantially uniform.

For example, second insulating layer 44 is a SiN film formed by the ALD. Second insulating layer 44 is denser than first insulating layer 42, i.e., has a film density higher than the film density of first insulating layer 42. The thickness of second insulating layer 44 formed by the ALD is smaller than the thickness of first insulating layer 42.

Source wiring 46 is disposed above first insulating layer 42. In the present embodiment, source wiring 46 is disposed to cover first insulating layer 42 and second insulating layer 44. Source wiring 46 penetrates through first insulating layer 42 to be connected to source electrode 32. Specifically, source wiring 46 is disposed to fill contact hole 43 and electrically connects a plurality of source electrodes 32 to each other.

Source wiring 46 is formed by using a conductive material, such as metal. For example, the same material as source electrode 32 can be used for source wiring 46.

Source wiring 46 is also disposed in edge termination area 3. Specifically, source wiring 46 is disposed to cover second insulating layer 44 in edge termination area 3. More specifically, source wiring 46 overlaps groove 40 in plan view. Source wiring 46 functions as a field plate when a source potential is applied to source wiring 46. Therefore, the electric field applied to the p-n junction interface in edge termination area 3 can be relaxed. Hence, it is possible to inhibit an increase in leakage current in an off state.

Third insulating layer 48 is disposed above source wiring 46. Specifically, third insulating layer 48 almost entirely covers transistor area 2, and includes an end that is positioned in edge termination area 3. Third insulating layer 48 is in contact with and covers the top surface of source wiring 46 and the top surface of second insulating layer 44 in the region where source wiring 46 is not disposed.

Third insulating layer 48 may be an insulating layer that includes an inorganic material as a main component. For example, third insulating layer 48 has a monolayer structure or a stacked structure each of which includes a film selected from the group including SiN, SiO₂, HfO₂, Al₂O₃, ZrO₂, AlN, HfON and ZrON.

Third insulating layer 48 is a so-called surface protective film. Third insulating layer 48 inhibits the entry of moisture and dust. Therefore, the reliability of nitride semiconductor device 1 can be increased.

As illustrated in FIG. 1, the end portion of third insulating layer 48 may be positioned to cover the end portion of second insulating layer 44 in edge termination area 3. In other words, the end surface of third insulating layer 48 may cover the end surface of source wiring 46 and a portion of the top surface of second insulating layer 44. For example, as illustrated in FIG. 2, third insulating layer 48 may be positioned outside relative to the end surface of source wiring 46 in plan view.

This allows the end portion of second insulating layer 44 to be covered by third insulating layer 48 without exposing the end portion of second insulating layer 44. With an increase in the region covered by third insulating layer 48, entry of moisture can be further inhibited. Therefore, the reliability of nitride semiconductor device 1 can be further increased.

### Manufacturing Method

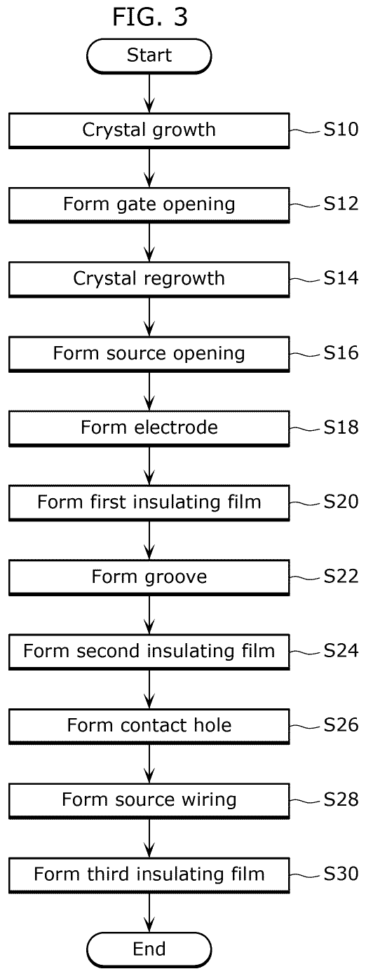

Next, the method for manufacturing nitride semiconductor device 1 according to the present embodiment will be described with reference to FIG. 3. FIG. 3 is a flowchart of the method for manufacturing nitride semiconductor device 1 according to the present embodiment.

As illustrated in FIG. 3, first, nitride semiconductors are grown by crystal growth on first main surface 10a of substrate 10 (S10). Specifically, n type GaN (drift layer 12), p type GaN (first base layer 14), and undoped GaN (second base layer 16) are continuously formed in this order by crystal growth. Crystal growth is performed by an epitaxial growth method, such as the MOVPE and HVPE. Doping of impurities into each layer may be performed by ion implantation after crystal growth.

Next, gate opening 20 is formed (S12). Specifically, gate opening 20 is formed by removing a portion of each of second base layer 16 and first base layer 14 so as to partially expose drift layer 12. Here, by removing the surface portion of drift layer 12 for a predetermined thickness, e.g., 300 nm, bottom 20a of gate opening 20 is formed below the bottom surface of first base layer 14.

The removal of second base layer 16 and first base layer 14 is performed by application and patterning of a resist and dry etching. Specifically, the resist is patterned and is then baked, and thus an end portion of the resist is inclined. Thereafter, dry etching is performed, and thus the shape of the resist is transferred, with the result that gate opening 20 having inclined side wall 20b is formed.

Next, nitride semiconductors are grown by crystal regrowth (S14). Specifically, undoped GaN (electron transport layer 22), undoped AlGaN (electron supply layer 24), and p type GaN or AlGaN (threshold adjustment layer 28) are continuously formed in this order by crystal growth (regrowth). Crystal growth is performed by an epitaxial growth method, such as the MOVPE and HVPE. By performing crystal regrowth after forming gate opening 20, semiconductor films each having a uniform thickness can be formed along the inner surface of gate opening 20.

Next, source opening 30 is formed at a position distant from gate opening 20 (S16). Specifically, following the crystal regrowth process (S14), source opening 30 is formed by etching threshold adjustment layer 28, electron supply layer 24, electron transport layer 22, and second base layer 16 so as to expose first base layer 14 in a region different from gate opening 20. At this time, the surface layer portion of first base layer 14 is also removed, so that bottom 30a of source opening 30 is formed below the bottom surface of second base layer 16. Source opening 30 is formed into a predetermined shape by, for example, patterning using photolithography and dry etching.

Threshold adjustment layer 28 is removed larger than source opening 30 so as not to contact source electrode 32 formed in source opening 30. This exposes the portion of the top surface of electron supply layer 24 in the vicinity of source opening 30.

At the same time as the formation of source opening 30, threshold adjustment layer 28, electron supply layer 24, electron transport layer 22, and second base layer 16 are also removed by etching in edge termination area 3. This exposes the top surface of first base layer 14 in edge termination area 3.

Next, each electrode of transistor area 2 is formed (S18). Specifically, source electrode 32, gate electrode 34, and drain electrode 36 are formed. Drain electrode 36 may be formed in a separate process. For example, drain electrode 36 may be formed in the process after third insulating layer 48 is formed. Either source electrode 32 or gate electrode 34 may be formed first.

Each electrode is formed by forming a conductive film by, for example, sputtering or vapor deposition, and then patterning the conductive film formed. Patterning is performed by, for example, etching or lift-off.

Next, first insulating layer 42 is formed above gate electrode 34 (S20). Specifically, first insulating layer 42 is formed by the plasma CVD. First insulating layer 42 is formed to entirely cover all the structural elements formed on the first main surface 10a side of substrate 10, such as gate electrode 34 and source electrode 32. First insulating layer 42 may be formed by sputtering.

Next, groove 40 is formed in edge termination area 3 (S22). Specifically, after forming first insulating layer 42, groove 40 is formed by removing first insulating layer 42 and first base layer 14 to expose a portion of drift layer 12 in edge termination area 3. At this time, the surface layer portion of drift layer 12 may also be removed. Removal of first insulating layer 42 and first base layer 14 is performed by application and patterning of a resist, and dry etching.

Next, second insulating layer 44 is formed to cover the side surface of groove 40 (S24). Specifically, second insulating layer 44 is formed by the ALD. Second insulating layer 44 is formed to entirely cover all the structural elements formed on the first main surface 10a side of substrate 10, such as groove 40 and first insulating layer 42. Second insulating layer 44 may be formed by the spin-coating, as described in detail below.

Next, contact hole 43 is formed (S26). Specifically, the portion of second insulating layer 44 in transistor area 2 is removed, and a portion of first insulating layer 42 is further removed to expose at least a portion of source electrode 32. Only the portion of first insulating layer 42 that overlaps source electrode 32 is removed. Removal of second insulating layer 44 and first insulating layer 42 is performed by, for example, patterning with photolithography and dry etching.

The removal of first insulating layer 42 to form contact hole 43 may be performed at the same time as the process of forming groove 40 (S22). In this case, second insulating layer 44 is formed in contact hole 43 in step S24. In step S26, second insulating layer 44 formed in contact hole 43 is removed to expose source electrode 32.

Next, source wiring 46 is formed (S28). Specifically, a conductive film is formed to entirely cover all the structural elements formed on the first main surface 10a side of substrate 10, such as second insulating layer 44 and first insulating layer 42. The conductive film is formed, for example, by sputtering or vapor deposition. By patterning the conductive film formed, source wiring 46 is formed. Patterning is performed by etching or lift-off.

Next, third insulating layer 48 is formed (S30). Specifically, third insulating layer 48 is formed to entirely cover all the structural elements formed on the first main surface 10a side of substrate 10, such as source wiring 46. Third insulating layer 48 is formed by the plasma CVD, spin coating, or ALD.

Through the above processes, nitride semiconductor device 1 illustrated in FIG. 1 and FIG. 2 can be manufactured.

As described above, the formation of groove 40 (S22) is performed after the formation of first insulating layer 42 (S20). Therefore, in side wall 40b of groove 40, the p-n junction interface between drift layer 12 and first base layer 14 is exposed in the process after first insulating layer 42 is formed.

The plasma CVD or sputtering used to form first insulating layer 42 is likely to cause process damage to the layer serving as a base layer during deposition. Therefore, when first insulating layer 42 is formed in groove 40, the p-n junction interface exposed to side wall 40b may degrade due to the process damage. According to the present embodiment, groove 40 can be formed after first insulating layer 42 is formed, thus eliminating the process damage caused during the formation of first insulating layer 42. Therefore, it is possible to prevent the damage caused during the formation of first insulating layer 42 from entering the p-n junction interface. As described above, second insulating layer 44 is formed by a method, such as the ALD, which causes little damage. This inhibits the damage to the p-n junction interface exposed to side wall 40b of groove 40. Thus, the degradation of the p-n junction interface is inhibited, and an increase in leakage current in an off state can be inhibited. In this way, according to the present embodiment, it is possible to achieve nitride semiconductor device 1 that has improved off characteristics.

### Embodiment 2

Next, Embodiment 2 will be described.

Embodiment 2 is different from Embodiment 1 mainly in the arrangement of the semiconductor multilayer film. The differences from Embodiment 1 will be mainly described below, and descriptions of shared features will be omitted or simplified.

### Configuration

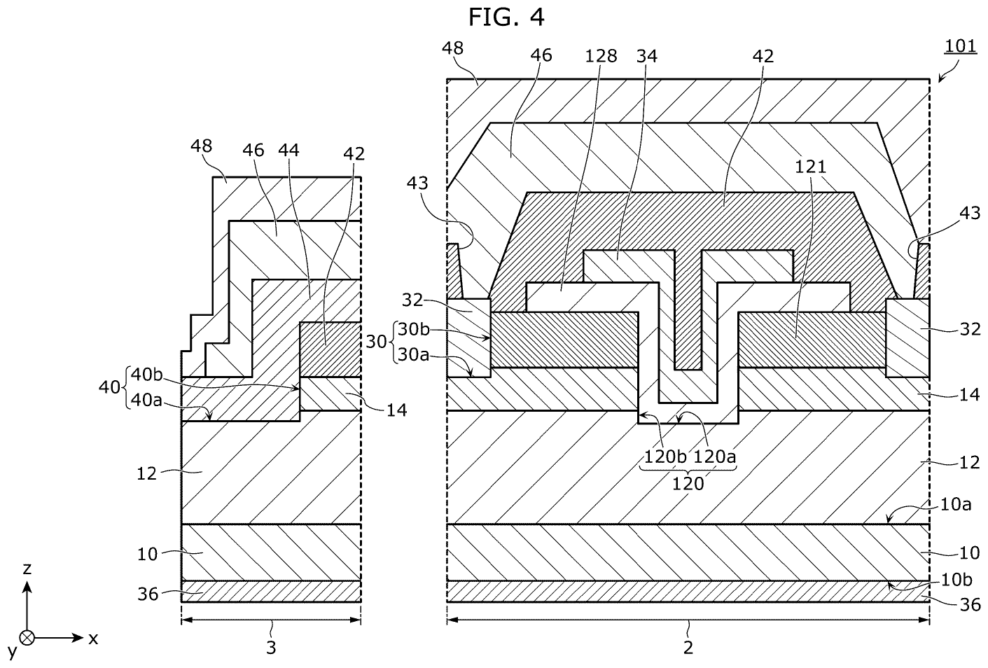

First, a configuration of a nitride semiconductor device according to the present embodiment will be described with reference to FIG. 4. FIG. 4 is a cross-sectional view of nitride semiconductor device 101 according to the present embodiment.

As illustrated in FIG. 4, nitride semiconductor device 101 is different from nitride semiconductor device 1 illustrated in FIG. 1 in that gate opening 120, channel layer 121, and gate insulating layer 128 are included instead of gate opening 20, semiconductor multilayer film 21, and threshold adjustment layer 28.

Channel layer 121 is an example of a third nitride semiconductor layer that includes a channel and is at least partially disposed above first base layer 14. Specifically, channel layer 121 is in contact with and covers the top surface of first base layer 14. Channel layer 121 is, for example, an n type GaN layer. Channel layer 121 includes a large amount of n type impurities, and has a low resistance.

Channel layer 121 is formed continuously by crystal growth such as the MOVPE, HVPE, or the like, following the formation of drift layer 12 and first base layer 14. Doping of impurities into channel layer 121 may be performed by ion implantation after crystal growth.

In the present embodiment, gate opening 120 is an example of a first opening, and penetrates through channel layer 121. Specifically, gate opening 120 penetrates through electron supply layer 124, electron transport layer 122, and first base layer 14 to reach drift layer 12. Bottom 120a of gate opening 120 serves as a portion of the top surface of drift layer 12.

As illustrated in FIG. 4, bottom 120a is positioned below the bottom surface of first base layer 14. The bottom surface of first base layer 14 corresponds to the interface between first base layer 14 and drift layer 12. Bottom 120a is, for example, parallel to first main surface 10a of substrate 10.

As illustrated in FIG. 4, the opening area of gate opening 120 is uniform regardless of the distance from substrate 10. Specifically, each side wall 120b of gate opening 120 is perpendicular to bottom 120a. In other words, the cross-sectional shape of gate opening 120 is a rectangle.

Alternatively, in a similar manner to gate opening 20 in Embodiment 1, the opening area of gate opening 120 may increase as the distance from substrate 10 increases. Specifically, side wall 120b of gate opening 120 may be inclined at an angle. For example, the cross-sectional shape of gate opening 120 may be an inverted trapezoid, or more specifically, is an inverted isosceles trapezoid.

Gate insulating layer 128 is disposed along the inner surface of gate opening 120 between the inner surface of gate opening 120 and gate electrode 34. Specifically, gate insulating layer 128 and gate electrode 34 are disposed in this order along the inner surface of gate opening 120. More specifically, a portion of gate insulating layer 128 is disposed along bottom 120a and side wall 120b of gate opening 120. The other portions of gate insulating layer 128 are disposed on the top surface of electron supply layer 124. Gate insulating layer 128 is in contact with the end surface of each of first base layer 14, electron transport layer 122, and electron supply layer 124 at side wall 120b of gate opening 120.

Gate insulating layer 128 is, for example, an insulating oxide film, such as SiO₂, SiN, or Al₂O₃. Gate insulating layer 128 may have a monolayer structure or a stacked structure.

When predetermined voltage is applied to gate electrode 34, an inverted region that is inverted to n type is formed in the vicinity of the end surface of p type first base layer 14 that is in contact with gate insulating layer 128. Since the inversion region functioning as a channel electrically connects electron transport layer 122 and drift layer 12, current flows between source electrode 32 and drain electrode 36. In this way, nitride semiconductor device 101 according to the present embodiment enables operation equivalent to a so-called MOSFET.

In nitride semiconductor device 101 according to the present embodiment, too, first insulating layer 42 is, for example, an insulating layer formed by the plasma CVD and including, as a main component, nitride that is an inorganic material. For example, first insulating layer 42 has a monolayer structure of SiN. Therefore, it is possible to inhibit the phenomenon in which switching is not properly performed under specific driving conditions, which is one of the problems to be solved. Thus, the reliability of the operation of nitride semiconductor device 101 can be increased.

In a similar manner to Embodiment 1, the end portion of first insulating layer 42 coincides with the end portion of groove 40 in plan view. Specifically, since groove 40 is formed after first insulating layer 42 is formed, the degradation of the p-n junction interface exposed to side wall 40b of groove 40 can be inhibited. Hence, it is possible to inhibit an increase in leakage current in an off state, leading to improved off characteristics.

In the present embodiment, the example in which nitride semiconductor device 101 includes channel layer 121 has been described. However, the present disclosure is not limited to such an example. For example, instead of channel layer 121, nitride semiconductor device 101 may include a plurality of semiconductor films having different bandgaps, in a similar manner to Embodiment 1. Specifically, nitride semiconductor device 101 may include a semiconductor multilayer film that includes an AlGaN layer and a GaN layer, and includes two-dimensional electron gas 26 generated in the vicinity of the heterointerface of AlGaN/GaN as a channel.

### Manufacturing Method

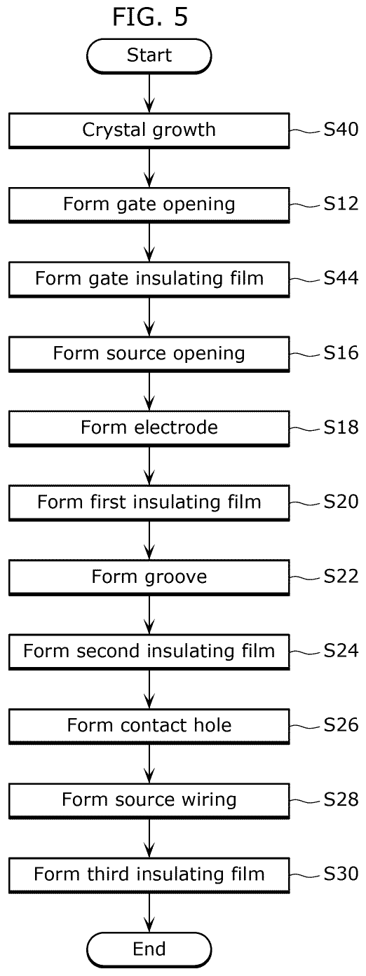

Next, a method for manufacturing nitride semiconductor device 101 according to the present embodiment will be described with reference to FIG. 5. FIG. 5 is a flowchart of the method for manufacturing nitride semiconductor device 101 according to the present embodiment. The differences from the method for manufacturing nitride semiconductor device 1 illustrated in FIG. 3 will be mainly described below.

As illustrated in FIG. 5, first, a nitride semiconductor is grown by crystal growth on first main surface 10a of substrate 10 (S40). Specifically, n⁻ type GaN (drift layer 12), p type GaN (first base layer 14), undoped GaN (electron transport layer 122), and undoped AlGaN (electron supply layer 124) are continuously formed in this order by crystal growth. Crystal growth is performed by epitaxial growth such as the MOVPE and HVPE. Doping of impurities to each layer may be performed by ion implantation after the crystal growth.

In the present embodiment, after the continuous formation from drift layer 12 to electron supply layer 124, gate opening 120 is formed (S12). In other words, crystal regrowth (S14 in FIG. 3) is not performed. Instead of the crystal regrowth, gate insulating layer 128 is formed after gate opening 120 is formed (S44). Gate insulating layer 128 is formed by, for example, the plasma CVD, ALD, or sputtering.

Subsequent steps are the same as the method for manufacturing nitride semiconductor device 1 illustrated in FIG. 3.

Therefore, in a similar manner to Embodiment 1, it is possible to inhibit leakage current in edge termination area 3 and to improve the operation reliability.

### Variations

Next, variations of the embodiments will be described.

Although the variations described below are variations of nitride semiconductor device 1 according to Embodiment 1, the variations can also be applied to nitride semiconductor device 101 according to Embodiment 2. When applied to nitride semiconductor device 101 according to Embodiment 2, the advantageous effects described below can also be obtained. The differences from Embodiment 1 will be mainly described below, and descriptions of shared features will be omitted or simplified.

### Variation 1

First, Variation 1 will be described. Variation 1 is different from Embodiment 1 in the position relationship of the second insulating layer.

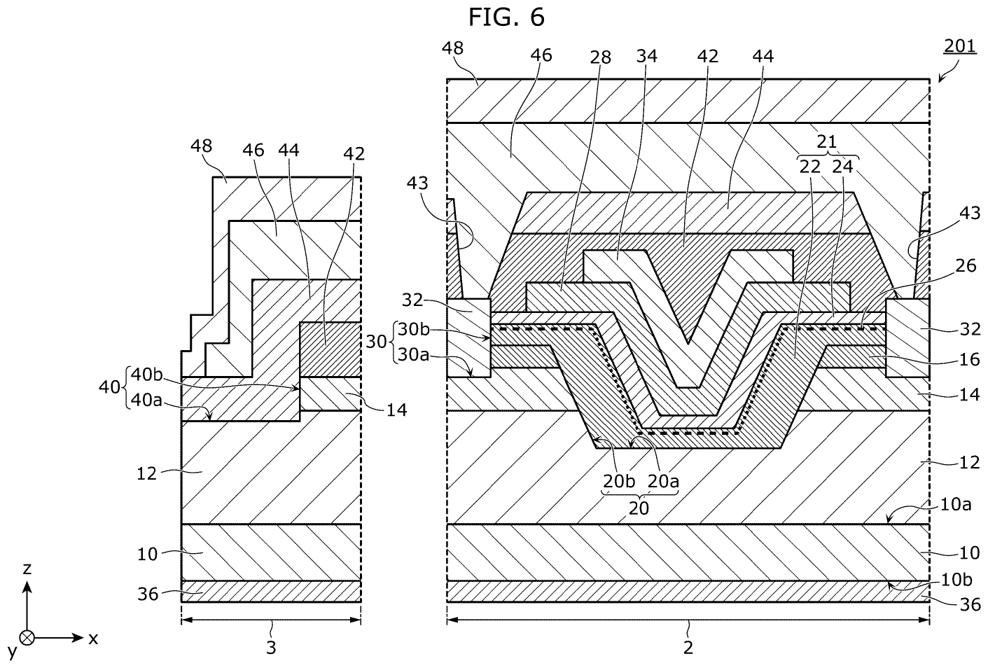

FIG. 6 is a cross-sectional view of nitride semiconductor device 201 according to Variation 1. As illustrated in FIG. 6, nitride semiconductor device 201 is different from nitride semiconductor device 1 illustrated in FIG. 1 in that second insulating layer 44 is also disposed in transistor area 2. In other words, second insulating layer 44 is disposed above first insulating layer 42, and overlaps gate electrode 34 in plan view.

This allows second insulating layer 44 to be formed over the entire nitride semiconductor device 201 when second insulating layer 44 is formed in edge termination area 3. For example, the patterning process of second insulating layer 44 can be omitted, thus simplifying the manufacturing process.

### Variation 2

Next, Variation 2 will be described.

Variation 2 is different from Variation 1 in the manufacturing method and shape of the second insulating layer. The differences from Variation 1 will be mainly described below, and descriptions of shared features will be omitted or simplified.

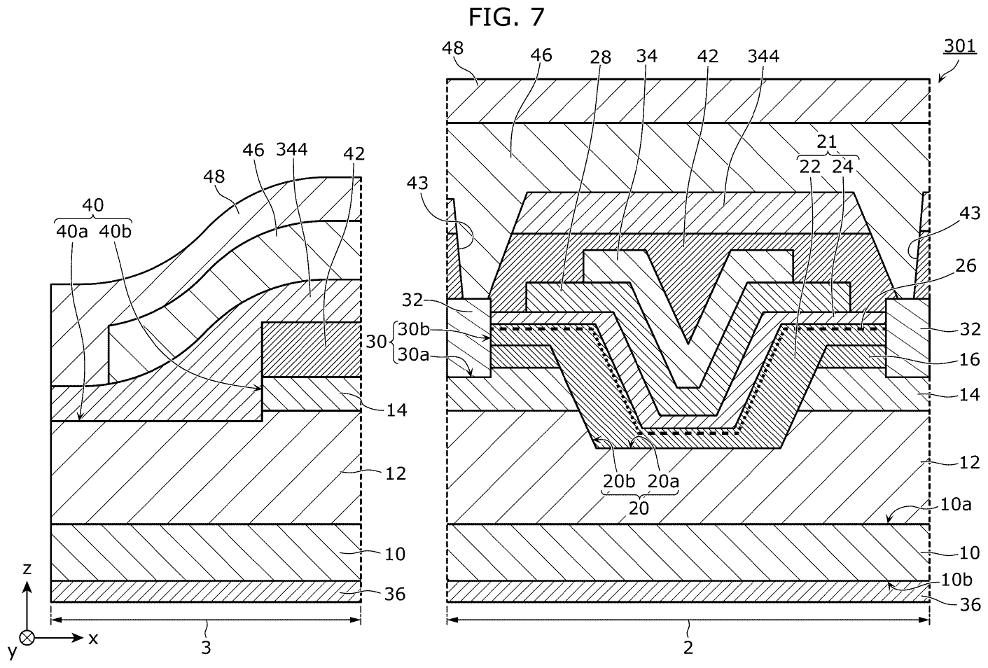

FIG. 7 is a cross-sectional view of nitride semiconductor device 301 according to Variation 2. As illustrated in FIG. 7, nitride semiconductor device 301 is different from nitride semiconductor device 201 according to Variation 1 in that second insulating layer 344 is included instead of second insulating layer 44.

The thickness of second insulating layer 344 is not uniform. Specifically, the thickness of the portion of second insulating layer 344 that is disposed in groove 40 is different from the thickness of the portion of second insulating layer 344 that overlaps gate electrode 34 in plan view.

Second insulating layer 344 has a monolayer structure including a film selected from the group including SiO₂, HfO₂, Al₂O₃, ZrO₂, AlN, HfON and ZrON. In Variation 2, second insulating layer 344 is formed by the spin coating. In the spin coating, an insulating layer material in liquid form is applied to the wafer, and the material is spread over the entire wafer by rotating the wafer, and then baking is performed. Moisture and organic components are removed by the baking to form second insulating layer 344. Second insulating layer 344, which is formed by the spin coating, is not formed uniformly across nitride semiconductor device 301, as illustrated in FIG. 7. Specifically, second insulating layer 344 is thicker in lower regions, such as the region on groove 40, and thinner and gentler in higher regions, such as the region on first insulating layer 42.

Unlike the deposition methods such as the plasma CVD and sputtering, the spin coating is capable of inhibiting process damages during deposition to the p-n junction interface of side wall 40b of groove 40. Hence, it is possible to inhibit an increase in leakage current in an off state, leading to improved off characteristics.

In Variation 2, although the example has been described where second insulating layer 344 is disposed at a position overlapping gate electrode 34 in plan view, second insulating layer 344 may be disposed only in edge termination area 3 in a similar manner to Embodiment 1. In other words, second insulating layer 344 does not have to overlap gate electrode 34 in plan view.

### Variation 3

Next, Variation 3 will be described.

Variation 3 is different from Embodiment 1 in the configuration of the first insulating layer. The differences from Embodiment 1 will be mainly described below, and descriptions of shared features will be omitted or simplified.

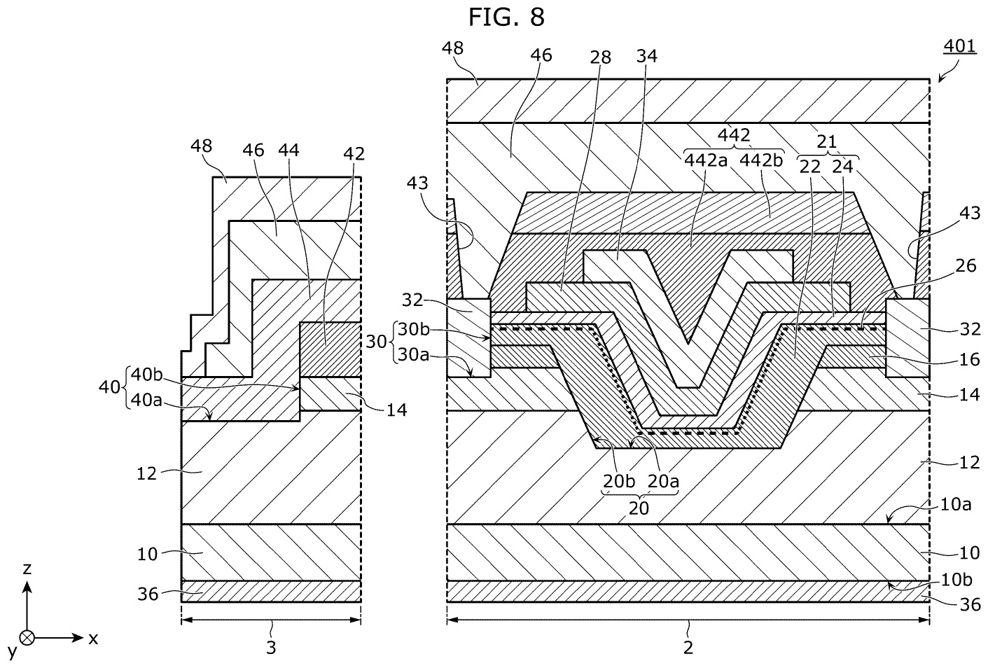

FIG. 8 is a cross-sectional view of nitride semiconductor device 401 according to Variation 3. As illustrated in FIG. 8, nitride semiconductor device 401 is different from nitride semiconductor device 1 according to Embodiment 1 in that first insulating layer 442 is included instead of first insulating layer 42.

In Variation 3, first insulating layer 442 has a stacked structure including a film selected from the group including SiN, SiO₂, HfO₂, Al₂O₃, ZrO₂, AlN, HfON and ZrON. Specifically, as illustrated in FIG. 8, first insulating layer 442 includes lower insulating layer 442a and upper insulating layer 442b. In FIG. 8, the stacked structure of two layers of insulating layers are illustrated, but it may be a stacked structure of three or more layers of insulating layers.

Lower insulating layer 442a is a lowermost insulating layer. Lower insulating layer 442a is in contact with gate electrode 34, threshold adjustment layer 28, and electron supply layer 24. Lower insulating layer 442a is SiN. Upper insulating layer 442b is formed by using a material other than SiN. Lower insulating layer 442a and upper insulating layer 442b are formed, for example, by the plasma CVD or sputtering.

In this way, by providing highly crystalline SiN formed by the plasma CVD or the like as lowermost lower insulating layer 442a, it is possible to inhibit the phenomenon in which switching is not properly performed under the specific drive conditions, which is one of the problems to be solved. In addition, the stacked structure of first insulating layer 442 allows the optimal film to be selected for each insulating layer, thereby further increasing the reliability of the device.

In Variation 3, although the example has been described where second insulating layer 44 is disposed only in edge termination area 3, second insulating layer 44 may also be disposed in transistor area 2 in a similar manner to Variation 1. In other words, second insulating layer 44 may overlap gate electrode 34 in plan view. Second insulation film 344 formed by the spin coating may be disposed instead of second insulating layer 44.

### Variation 4

Next, Variation 4 will be described.

Variation 4 is different from Embodiment 1 in the configuration of the second insulating layer. The differences from Embodiment1 will be mainly described below, and descriptions of shared features will be omitted or simplified.

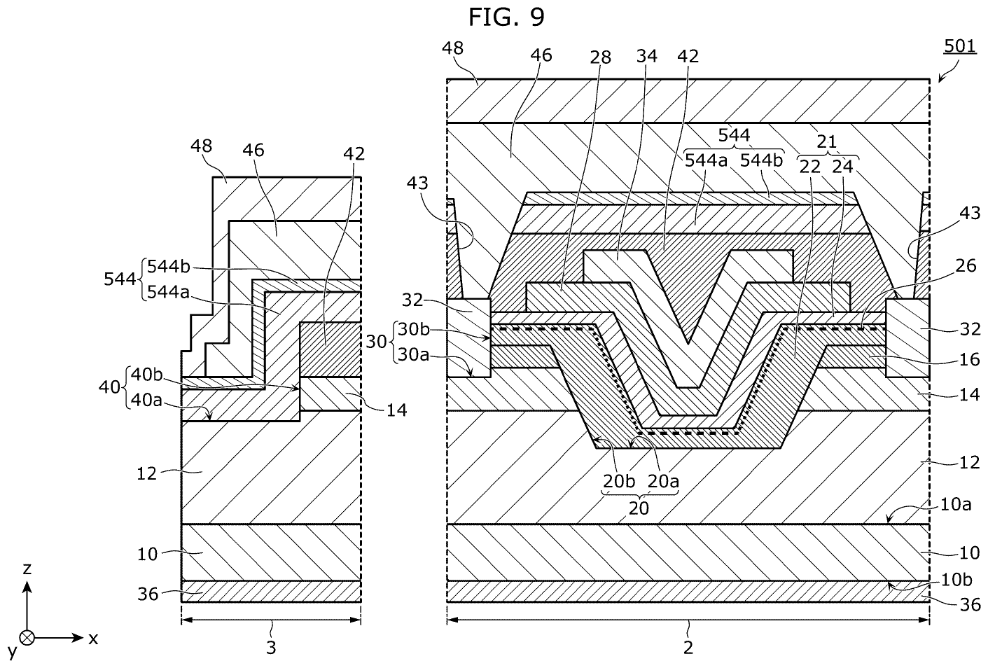

FIG. 9 is a cross-sectional view of nitride semiconductor device 501 according to Variation 4. As illustrated in FIG. 9, nitride semiconductor device 501 is different from nitride semiconductor device 1 according to Embodiment 1 in that second insulating layer 544 is included instead of second insulating layer 44.

In Variation 4, second insulating layer 544 has a stacked structure including a film selected from the group including SiN, SiO₂, HfO₂, Al₂O₃, ZrO₂, AlN, HfON and ZrON. Specifically, as illustrated in FIG. 9, second insulating layer 544 includes lower insulating layer 544a and upper insulating layer 544b. In FIG. 9, although the stacked structure of two layers of insulating layers are illustrated, it may be a stacked structure of three or more layers of insulating layers.

Lower insulating layer 544a is a lowermost insulating layer. Lower insulating layer 544a is in contact with and covers bottom 40a and side wall 40b of groove 40. For example, lower insulating layer 544a is a film that includes SiO₂ formed by the spin coating. Lower insulating layer 544a may be an insulating layer formed by the ALD.

Upper insulating layer 544b is, for example, a film that includes Al₂O₃ and is formed by the ALD. Upper insulating layer 544b may be an insulating layer formed by the spin coating. Upper insulating layer 544b may be an insulating layer formed by the plasma CVD.

In this way, by providing an insulating layer formed by a method that is less likely to cause damage to the p-n junction interface, such as the spin coating or ALD, as lowermost lower insulating layer 544a, an increase in leakage current in an off state can be inhibited. In addition, the reliability of nitride semiconductor device 501 can be further improved by including a film having low water permeability, such as Al₂O₃.

In Variation 4, although the example has been described where second insulating layer 544 is also disposed in transistor area 2, second insulating layer 544 may be disposed only in edge termination area 3 in a similar manner to Embodiment 1. In other words, second insulating layer 544 does not have to overlap gate electrode 34 in plan view. In addition, first insulation film 442 having a stacked structure may be disposed instead of first insulating layer 42.

### Variation 5

Next, Variation 5 will be described.

Variation 5 is different from Embodiment 1 in the position of the end portion of the first insulating layer. The differences from Embodiment 1 will be mainly described below, and descriptions of shared features will be omitted or simplified.

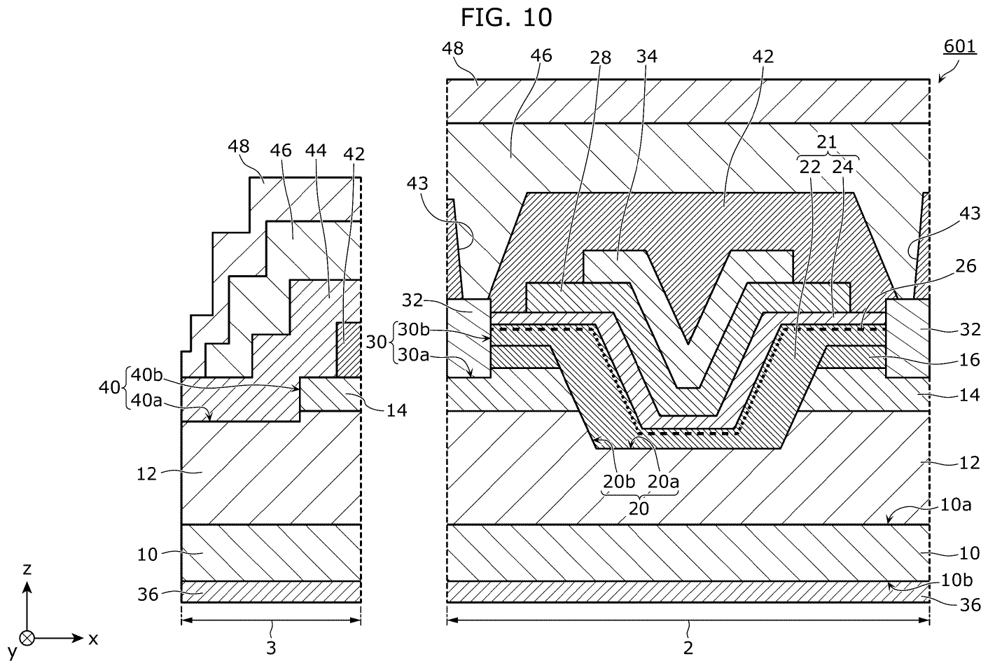

FIG. 10 is a cross-sectional view of nitride semiconductor device 601 according to Variation 5. As illustrated in FIG. 10, nitride semiconductor device 601 is different from nitride semiconductor device 1 according to Embodiment 1 in that the end portion of first insulating layer 42 is positioned inside relative to the end portion of groove 40. Specifically, the end portion of first insulating layer 42 is positioned inside relative to the end portion of groove 40 and outside relative to the outermost periphery of source electrode 32. In other words, the end portion of first insulating layer 42 and the end portion of first base layer 14 may form a level difference. In other words, the top surface of first base layer 14 is in contact with and completely covered by second insulating layer 44.

In this case, too, in a similar manner to Embodiment 1, the degradation of the p-n junction interface is inhibited, thereby inhibiting an increase in leakage current in an off state.

In Variation 5, although the example has been described where second insulating layer 44 is disposed only in edge termination area 3, second insulating layer 44 may also be disposed in transistor area 2 in a similar manner to Variation 1. In other words, second insulating layer 44 may overlap gate electrode 34 in plan view. Moreover, first insulation film 442 having a stacked structure may be disposed instead of first insulating layer 42. Second insulation film 544 having a stacked structure may be disposed instead of second insulating layer 44.

### Other Embodiments

The nitride semiconductor device and the method for manufacturing the nitride semiconductor device according to one or more aspects have been described based on the embodiments. However, the present disclosure is not limited to these embodiments. Embodiments obtained by performing, on the embodiments, various variations conceived by a person skilled in the art and embodiments established by combining structural elements in different embodiments are also included in the scope of the present disclosure as long as they do not depart from the spirit of the present disclosure.

For example, source opening 30 does not have to be disposed. In this case, source electrode 32 is disposed on the top surface of semiconductor multilayer film 21, at a position distant from threshold adjustment layer 28. The process of forming source opening 30 (S16 in FIG. 3) can be omitted, thereby simplifying the manufacturing process.

Moreover, for example, drift layer 12 may have a graded structure in which the impurity concentration (donor concentration) is gradually reduced from the substrate 10 side to the first base layer 14 side. The donor concentration may be controlled by Si that serves as a donor or by carbon that serves as an acceptor for compensating for Si. Alternatively, drift layer 12 may have a stacked structure of a plurality of nitride semiconductor layers having different impurity concentrations.

Moreover, for example, edge termination area 3 does not have to include the end surface of nitride semiconductor device 1. Edge termination area 3 is a portion for separating transistor area 2 from other devices. Other elements may be disposed in a region adjacent to transistor area 2 through edge termination area 3. For example, examples of the other elements include a pn diode that uses a p-n junction between drift layer 12 and first base layer 14. Nitride semiconductor device 1 may include transistor area 2, edge termination area 3, and a pn diode.

For example, first insulating layer 42 can be formed by the ALD. However, it takes a long time to form first insulating layer 42 having a sufficient thickness. Therefore, first insulating layer 42 can be formed by the plasma CVD or sputtering to improve production efficiency.

The first conductivity type may be p type, p³⁰ type, or p⁻ type, and the second conductivity type may be n type, n⁺ type, or n⁻ type.

In the embodiments described above, various changes, replacements, additions, omissions, and the like can be performed without departing from the scope of claims or the scope equivalent thereto.

### INDUSTRIAL APPLICABILITY

The present disclosure can be used as a nitride semiconductor device in which off characteristics and switching characteristics are improved, and can be used, for example, as a power device, such as a power transistor used in an inverter circuit, a power supply circuit and the like of a consumer device such as a television, an in-vehicle device, and an industrial apparatus.

1. A nitride semiconductor device comprising:
a substrate;
a first semiconductor layer of a first conductivity type that is disposed above the substrate;
a second semiconductor layer of a second conductivity type that is disposed above the first semiconductor layer;
a third semiconductor layer that includes a channel and is at least partially disposed above the second semiconductor layer;
a gate electrode that is disposed above the first semiconductor layer;
a source electrode that is spaced apart from the gate electrode;
a drain electrode that is disposed below the substrate;
a first insulating layer that is disposed above the gate electrode and includes nitride as a main component; and
a second insulating layer that is disposed to cover a side surface of a groove that is provided in an edge termination area of the nitride semiconductor device, the groove penetrating through the first insulating layer and the second semiconductor layer to reach the first semiconductor layer,
wherein, in a plan view, an end portion of the first insulating layer coincides with an end portion of the groove, or is positioned inside relative to the end portion of the groove and outside relative to an outermost periphery of the source electrode.

2. The nitride semiconductor device according to claim 1, further comprising:
a fourth semiconductor layer that is disposed above the second semiconductor layer,
wherein the third semiconductor layer includes a plurality of semiconductor films having different bandgaps,
the channel is two-dimensional electron gas generated at an interface between adjacent ones of the plurality of semiconductor films,
the gate electrode overlaps, in the plan view, a first opening that penetrates through the fourth semiconductor layer and the second semiconductor layer to reach the first semiconductor layer, and
a portion of the third semiconductor layer is disposed along an inner surface of the first opening between the inner surface of the first opening and the gate electrode.

3. The nitride semiconductor device according to claim 2, further comprising:
a fifth semiconductor layer of the second conductivity type that is disposed between the third semiconductor layer and the gate electrode.

4. The nitride semiconductor device according to claim 1,
wherein the gate electrode overlaps, in the plan view, a first opening that penetrates through the third semiconductor layer and the second semiconductor layer to reach the first semiconductor layer,
the nitride semiconductor device further comprises:
a gate insulating layer that is disposed along an inner surface of the first opening between the inner surface of the first opening and the gate electrode.

5. The nitride semiconductor device according to claim 1,
wherein the first insulating layer has a substantially uniform thickness.

6. The nitride semiconductor device according to claim 1,
wherein the second insulating layer is disposed above the first insulating layer and overlaps the gate electrode in the plan view.

7. The nitride semiconductor device according to claim 6, wherein a thickness of a portion of the second insulating layer that is disposed in the groove is different from a thickness of a portion of the second insulating layer that overlaps the gate electrode in the plan view.

8. The nitride semiconductor device according to claim 1,
wherein the first insulating layer has a monolayer structure of SiN or a stacked structure in which a lowermost layer is a SiN layer.

9. The nitride semiconductor device according to claim 1,
wherein the second insulating layer has a monolayer structure or a stacked structure each of which includes a film selected from a group including SiN, SiO₂, HfO₂, Al₂O₃, ZrO₂, AlN, HfON, and ZrON.

10. The nitride semiconductor device according to claim 1, further comprising:
source wiring that is disposed above the first insulating layer and penetrates through the first insulating layer to be connected to the source electrode; and
a third insulating layer that is disposed above the source wiring.

11. A method for manufacturing a nitride semiconductor device that includes:
a substrate;
a first semiconductor layer of a first conductivity type that is disposed above the substrate;
a second semiconductor layer of a second conductivity type that is disposed above the first semiconductor layer;
a third semiconductor layer that includes a channel and is at least partially disposed above the second semiconductor layer;
a gate electrode that is disposed above the first semiconductor layer;
a source electrode that is spaced apart from the gate electrode; and
a drain electrode that is disposed below the substrate, the method for manufacturing the nitride semiconductor device comprising:
forming, above the gate electrode, a first insulating layer that includes nitride as a main component;
forming a groove in an edge termination area of the nitride semiconductor device, the groove penetrating through the first insulating layer and the second semiconductor layer to reach the first semiconductor layer; and
forming a second insulating layer to cover a side surface of the groove,
wherein, in a plan view, an end portion of the first insulating layer coincides with an end portion of the groove, or is positioned inside relative to the end portion of the groove and outside relative to an outermost periphery of the source electrode.

12. The method for manufacturing the nitride semiconductor device according to claim 11,
wherein, in the forming of the first insulating layer, the first insulating layer is formed by plasma chemical vapor deposition (CVD).

13. The method for manufacturing the nitride semiconductor device according to claim 11,
wherein, in the forming of the second insulating layer, the second insulating layer is formed by spin coating.
